(19) United States
(12) Patent Application Publication
(10) Pub. No.: US 2026/0123412 A1
(43) Pub. Date: Apr. 30, 2026

(54) SMALL FORM FACTOR SEMICONDUCTOR PACKAGE WITH LOW ELECTROMIGRATION

(71) Applicant: TEXAS INSTRUMENTS INCORPORATED, Dallas, TX (US)

(72) Inventors: Sylvester ANKAMAH-KUSI, McKinney, TX (US); Yutaka SUZUKI, Allen, TX (US); Guangxu LI, Allen, TX (US); Rajen Manicon MURUGAN, Dallas, TX (US); Harshpreet Singh Phull BAKSHI, Dallas, TX (US); Blake TRAVIS, Richardson, TX (US); Jie CHEN, Plano, TX (US)

(21) Appl. No.: 18/934,059

(22) Filed: Oct. 31, 2024

(51) Int. Cl. H01L 23/00; H01L 21/56; H01L 23/367; H01L 23/498

(52) U.S. Cl. CPC H10W 40/226; H10W 70/65; H10W 74/014; H10W 74/016; H10W 72/01235; H10W 72/0198; H10W 72/07236; H10W 72/221; H10W 72/232; H10W 72/248; H10W 72/252; H10W 72/325; H10W 72/353; H10W 74/15; H10W 90/724; H10W 90/734

(57) ABSTRACT

In examples, a semiconductor package includes a semiconductor die having a device side in which circuitry is formed; multiple copper posts coupled to the device side of the semiconductor die; a substrate coupled to the multiple copper posts by solder joints, the substrate comprising: cylindrical copper pillars extending from the solder joints on a top surface of the substrate to a bottom surface of the substrate, the copper pillars having circular or ovoid bottom surfaces exposed to the bottom surface of the substrate; and a build-up film between and physically contacting the copper pillars. The package also includes a mold compound physically contacting the semiconductor die, the multiple copper posts, and the top surface of the substrate.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die may then be coupled to a substrate or die pad. The resulting structure may be subsequently covered with a mold compound to produce a package.

### SUMMARY

In examples, a semiconductor package includes a semiconductor die having a device side in which circuitry is formed; multiple copper posts coupled to the device side of the semiconductor die; a substrate coupled to the multiple copper posts by solder joints, the substrate comprising: cylindrical copper pillars extending from the solder joints on a top surface of the substrate to a bottom surface of the substrate, the copper pillars having circular or ovoid bottom surfaces exposed to the bottom surface of the substrate; and a build-up film between and physically contacting the copper pillars. The package also includes a mold compound physically contacting the semiconductor die, the multiple copper posts, and the top surface of the substrate.

In examples, a method for manufacturing a semiconductor package includes forming a substrate by plating multiple cylindrical copper pillars and covering the multiple cylindrical copper pillars with a build-up film, the build-up film between and contacting the multiple cylindrical copper pillars; coupling copper posts to a device side of a semiconductor wafer, the device side including circuitry; partially cutting through the semiconductor wafer from the device side of the semiconductor wafer to form cavities; applying a mold compound to the device side of the semiconductor wafer and in the cavities; thinning the mold compound to expose the copper posts; curing the mold compound; backgrinding a non-device side of the semiconductor wafer opposite the device side until the semiconductor wafer is divided into multiple semiconductor dies; cutting through the mold compound to separate the multiple semiconductor dies from each other; coupling the multiple semiconductor dies to the multiple cylindrical copper pillars of the substrate; and cutting through the substrate in between the multiple semiconductor dies to form individual semiconductor packages.

### BRIEF DESCRIPTION OF THE DRAWINGS

FIG. 1A is a profile, cross-sectional view of a small form factor semiconductor package with low electromigration, in accordance with various examples.

FIG. 1B is a perspective view of a small form factor semiconductor package with low electromigration, in accordance with various examples.

FIG. 1C is a bottom-up view of a small form factor semiconductor package with low electromigration, in accordance with various examples.

FIG. 1D is a top-down view of a small form factor semiconductor package with low electromigration, in accordance with various examples.

FIG. 2A is a flow diagram of a method for manufacturing part of a small form factor semiconductor package with low electromigration, in accordance with various examples.

FIG. 2B is a flow diagram of a method for manufacturing part of a small form factor semiconductor package with low electromigration, in accordance with various examples.

FIG. 3A1 is a cross-sectional view of a portion of a process flow for manufacturing a small form factor semiconductor package with low electromigration, in accordance with various examples.

FIG. 3A2 is a top-down view of a portion of a process flow for manufacturing a small form factor semiconductor package with low electromigration, in accordance with various examples.

FIG. 3B1 is a cross-sectional view of a portion of a process flow for manufacturing a small form factor semiconductor package with low electromigration, in accordance with various examples.

FIG. 3B2 is a top-down view of a portion of a process flow for manufacturing a small form factor semiconductor package with low electromigration, in accordance with various examples.

FIG. 3C1 is a cross-sectional view of a portion of a process flow for manufacturing a small form factor semiconductor package with low electromigration, in accordance with various examples.

FIG. 3C2 is a top-down view of a portion of a process flow for manufacturing a small form factor semiconductor package with low electromigration, in accordance with various examples.

FIG. 3D1 is a cross-sectional view of a portion of a process flow for manufacturing a small form factor semiconductor package with low electromigration, in accordance with various examples.

FIG. 3D2 is a top-down view of a portion of a process flow for manufacturing a small form factor semiconductor package with low electromigration, in accordance with various examples.

FIG. 3E1 is a cross-sectional view of a portion of a process flow for manufacturing a small form factor semiconductor package with low electromigration, in accordance with various examples.

FIG. 3E2 is a top-down view of a portion of a process flow for manufacturing a small form factor semiconductor package with low electromigration, in accordance with various examples.

FIG. 3F1 is a cross-sectional view of a portion of a process flow for manufacturing a small form factor semiconductor package with low electromigration, in accordance with various examples.

FIG. 3F2 is a top-down view of a portion of a process flow for manufacturing a small form factor semiconductor package with low electromigration, in accordance with various examples.

FIG. 3G1 is a cross-sectional view of a portion of a process flow for manufacturing a small form factor semiconductor package with low electromigration, in accordance with various examples.

FIG. 3G2 is a top-down view of a portion of a process flow for manufacturing a small form factor semiconductor package with low electromigration, in accordance with various examples.

FIG. 3H1 is a cross-sectional view of a portion of a process flow for manufacturing a small form factor semiconductor package with low electromigration, in accordance with various examples.

FIG. 3H2 is a top-down view of a portion of a process flow for manufacturing a small form factor semiconductor package with low electromigration, in accordance with various examples.

FIG. 3I1 is a cross-sectional view of a portion of a process flow for manufacturing a small form factor semiconductor package with low electromigration, in accordance with various examples.

FIG. 3I2 is a top-down view of a portion of a process flow for manufacturing a small form factor semiconductor package with low electromigration, in accordance with various examples.

FIG. 3J1 is a cross-sectional view of a portion of a process flow for manufacturing a small form factor semiconductor package with low electromigration, in accordance with various examples.

FIG. 3J2 is a top-down view of a portion of a process flow for manufacturing a small form factor semiconductor package with low electromigration, in accordance with various examples.

FIG. 3K1 is a cross-sectional view of a portion of a process flow for manufacturing a small form factor semiconductor package with low electromigration, in accordance with various examples.

FIG. 3K2 is a top-down view of a portion of a process flow for manufacturing a small form factor semiconductor package with low electromigration, in accordance with various examples.

FIG. 3L1 is a cross-sectional view of a portion of a process flow for manufacturing a small form factor semiconductor package with low electromigration, in accordance with various examples.

FIG. 3L2 is a top-down view of a portion of a process flow for manufacturing a small form factor semiconductor package with low electromigration, in accordance with various examples.

FIG. 3M1 is a cross-sectional view of a portion of a process flow for manufacturing a small form factor semiconductor package with low electromigration, in accordance with various examples.

FIG. 3M2 is a top-down view of a portion of a process flow for manufacturing a small form factor semiconductor package with low electromigration, in accordance with various examples

FIG. 4 is a block diagram of an electronic device including a small form factor semiconductor package with low electromigration, in accordance with various examples.

### DETAILED DESCRIPTION

Wafer-level chip-scale packages (WCSPs) offer a compact form factor due at least in part to the absence of a mold compound. However, this packaging method has limitations in terms of electromigration characteristics, which negatively affect the current handling capabilities of the WCSP. The large solder-to-copper ratio, with relatively large solder balls and a relatively thin copper redistribution layer (RDL), contributes to excessive electromigration. The thin copper RDL, typically around 10 microns thick, exacerbates this issue by being unable to effectively manage the higher current demands, thus limiting WCSP's application in high-current environments.

On the other hand, flip-chip on lead (FCL) packages, in which the semiconductor die is “flipped” upside down so that the device side of the semiconductor die in which circuitry is formed is facing downward toward the package leads, have superior electromigration characteristics. These superior electromigration properties lead to higher current handling capability. The superior electromigration properties are due to the relatively small solder-to-copper ratio, with a thicker copper post (around 50 microns) and thinner solder (around 20 microns). The thick copper posts in FCL packages reduce electromigration and improve current handling capability. However, FCL packages have larger form factors, in some cases representing a more than 30% increase in size.

In some applications, both small form factors (e.g., WCSP form factors) and high current handling capability are needed, but neither WCSPs nor FCL packages provide this combination. WCSPs sacrifice current handling capability for form factor, while FCL packages sacrifice form factor for current handling capability, creating a trade-off between these two properties.

This description presents various examples of a semiconductor package that resolves the technical challenge described above by providing low electromigration and high current capability in a small form factor. Specifically, the semiconductor packages described herein may have the same or similar form factor as a WCSP, while maintaining a relatively low solder-to-copper ratio, thus providing low electromigration and high current handling capability. By providing both form factor and current handling advantages, the semiconductor packages described herein are useful in applications where both small form factor and high current handling capability are needed. In some examples, a semiconductor package includes a semiconductor die having a device side in which circuitry is formed, and multiple copper posts coupled to the device side of the semiconductor dic. The semiconductor package includes a substrate coupled to the multiple copper posts by solder joints. The substrate includes cylindrical copper pillars extending from the solder joints on a top surface of the substrate to a bottom surface of the substrate, the copper pillars having circular or ovoid bottom surfaces exposed to the bottom surface of the substrate in an array, where a solder-to-copper volumetric ratio from one of the copper posts to one of the copper pillars via one of the solder joints ranges from 0.08 to 0.13. The substrate also includes a build-up film between and physically contacting the copper pillars. The semiconductor package includes a mold compound physically contacting the semiconductor die, the multiple copper posts, and the top surface of the substrate. A ratio of an area of a top surface of the mold compound in the horizontal plane to an area of a non-device side of the semiconductor die opposite the device side is at least 0.90.

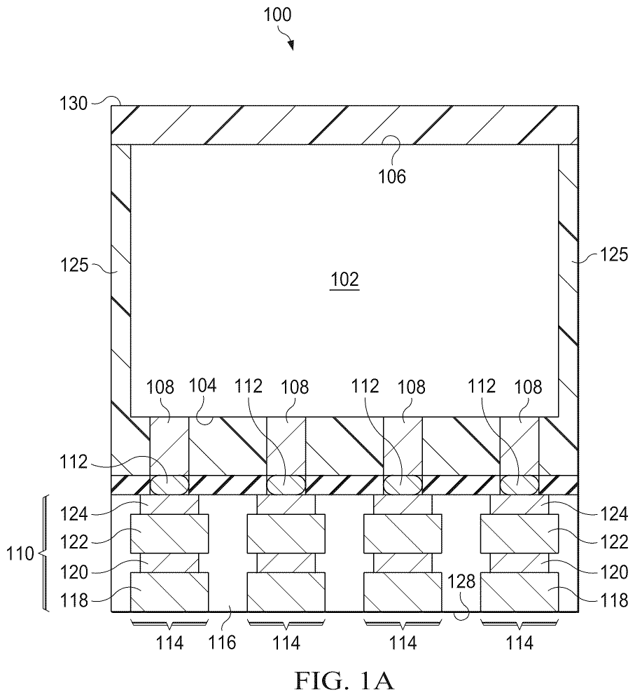

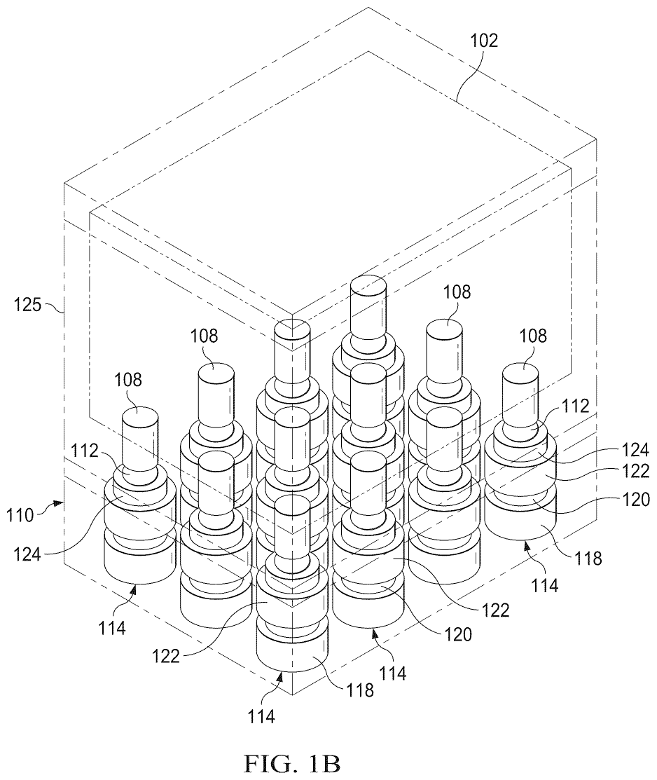

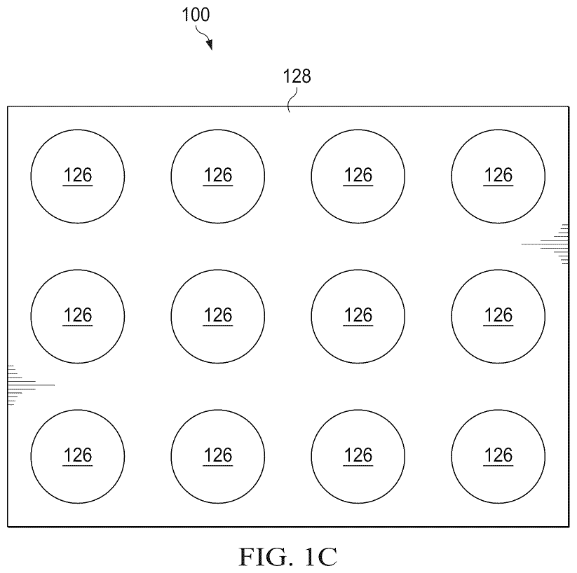

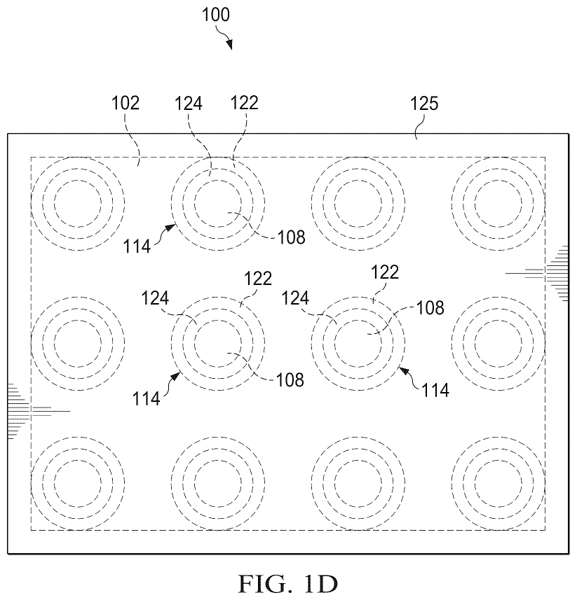

FIG. 1A is a profile, cross-sectional view of a small form factor semiconductor package 100 with low electromigration, in accordance with various examples. FIG. 1B is a perspective view of the semiconductor package 100 with low electromigration, in accordance with various examples. FIG. 1C is a bottom-up view of the semiconductor package 100 with low electromigration, in accordance with various examples. FIG. 1D is a top-down view of the semiconductor package 100 with low electromigration, in accordance with various examples. Specifically, FIG. 1A shows a semiconductor package 100 that includes a semiconductor die 102 (e.g., a silicon or gallium nitride die). The semiconductor die 102 may include a device side 104 in which circuitry is formed, and a non-device side 106 opposite the device side 104. Copper posts 108 are coupled to the device side 104 of the semiconductor die 102, for example, to metal layer(s) on the device side 104 of the semiconductor die 102 that couple to circuitry of the semiconductor die 102. The semiconductor package 100 includes a substrate 110 that is coupled to the copper posts 108 by solder joints 112.

The substrate 110 may include multiple cylindrical copper pillars 114 and may include a dielectric 116, such as a build-up film (e.g., AJINOMOTO® build-up film, or ABF), in between and physically contacting the cylindrical copper pillars 114. In examples, the build-up film (BUF) may include an epoxy resin, filler particles (e.g., ceramic filler particles), and a curing agent, although the precise composition of various BUFs may vary. Each cylindrical copper pillar 114 may include any suitable number of metal layers and vias coupled to the metal layers. For example, in FIG. 1A, each cylindrical copper pillar 114 includes a metal layer 118, a via 120 coupled to the metal layer 118, a metal layer 122 coupled to the via 120, and a via 124 coupled to the metal layer 122. The via 124 is coupled to a respective solder joint 112. A mold compound 125 covers and physically contacts the semiconductor die 102, the copper posts 108, the substrate 110, and the solder joints 112.

Although the cylindrical copper pillars 114 are depicted as including two metal layers (with their respective, corresponding vias), in examples, fewer or more metal layers may be included (with their respective, corresponding vias). A single metal layer (with corresponding via) may be preferable to minimize package size and cost while efficiently providing current through the substrate 110. Accordingly, some example substrates 110 include only a single metal layer with a single corresponding via layer in each of the cylindrical copper pillars 114. In some examples, the metallization in the substrate 110 extends only vertically, and no metallization in the substrate 110 has a length extending in the horizontal direction.

As the bottom-up view of FIG. 1C shows, bottom surfaces 126 of the cylindrical copper pillars 114 are exposed to a bottom surface 128 of the substrate 110. The bottom surfaces 126 may have a circular or ovoid shape in the horizontal plane, as FIG. 1C shows. This circular or ovoid shape mimics the contact point of a solder ball on the bottom side of a WCSP, which, upon reflow, would be circular or ovoid in the horizontal plane. Further, the bottom surfaces 126 may be arranged in a multi-dimensional array, such as in rows and columns, as shown. In this way, the semiconductor package 100 mimics the footprint and form factor of WCSPs, making the semiconductor package 100 a suitable replacement for WCSPs in at least the spatial sense.

Each of the solder joints 112 has a thickness ranging from 10 microns to 30 microns, with a thickness below this range being disadvantageous because the interconnect will become excessively rigid, leading to cracking, and with a thickness above this range being disadvantageous because of unacceptably diminished electromigration performance. Each of the copper posts 108 has a thickness ranging from 40 microns to 60 microns, with a thickness below this range being disadvantageous because it leads to poor mold compound flow and mold compound voiding, and with a thickness above this range being disadvantageous because of unacceptably increased manufacturing costs. Each of the cylindrical copper pillars 114 has a thickness ranging from 100 microns to 200 microns, with a thickness below this range being disadvantageous because of unacceptably diminished thermal performance, and with a thickness above this range being disadvantageous because of significant increases in manufacturing cost. The metal layers 118 and 122 have diameters ranging from 300 microns to 450 microns, mimicking the diameters of standard solder balls. The vias 120 and 124 are offset from the periphery of the metal layers 118 and 122 by 25-35 microns for manufacturability. Thus, the metal layers 118 and 122 have larger horizontal areas than the vias 120 and 124.

As described, the copper posts 108 may include copper. The cylindrical copper pillars 114 also may include copper. The solder joints 112 may include solder. In combination, the copper posts 108, solder joints 112, and cylindrical copper pillars 114 form an electrical pathway between the device side 104 of the semiconductor die 102 and any electrical component (e.g., a printed circuit board (PCB)) that may be coupled to the cylindrical copper pillars 114. This pathway has a solder-to-copper volumetric ratio ranging from 0.08 to 0.13. A solder-to-copper volumetric ratio below this range is disadvantageous because of the substantially increased cost of plating more copper and/or mechanical problems resulting from inadequate solder (e.g., detachment), and a solder-to-copper volumetric ratio above this range is disadvantageous because of diminished electromigration performance. A lower solder-to-copper volumetric ratio is useful because it mitigates electromigration, thereby boosting the current carrying capability of the semiconductor package 100.

As described, the circular or ovoid shaped bottom surfaces 126 shown in FIG. 1C help the semiconductor package 100 mimic the footprint and form factor of WCSPs. To further mimic the footprint and form factor of WCSPs, the size of the mold compound 125 is negligibly larger than the size of the semiconductor die 102. Specifically, a ratio of the horizontal area of the non-device side 106 of the semiconductor die 102 (e.g., the top surface of the semiconductor die 102) to the horizontal area of a top surface 130 of the mold compound 125 is at least 0.90. The closer this ratio approaches 1.0, the more the semiconductor package 100 footprint and form factor resemble those of WCSPs.

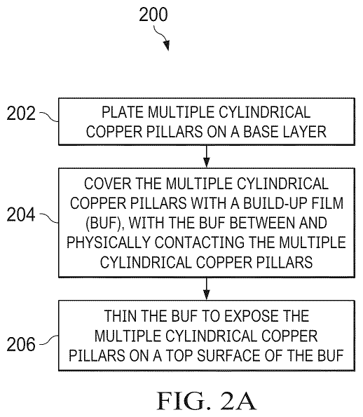

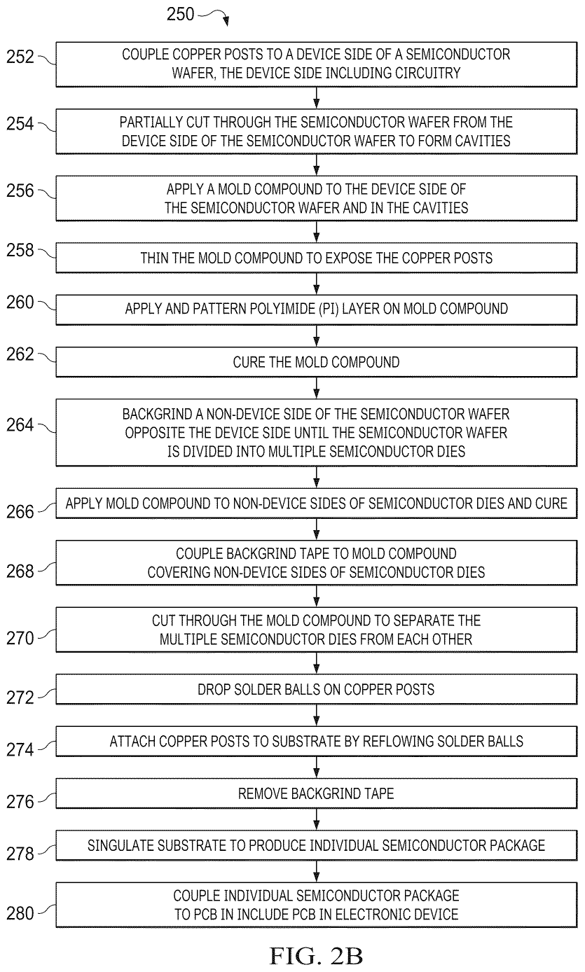

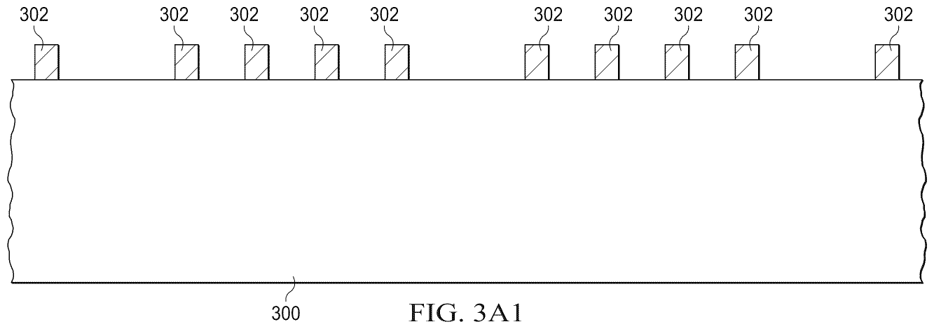

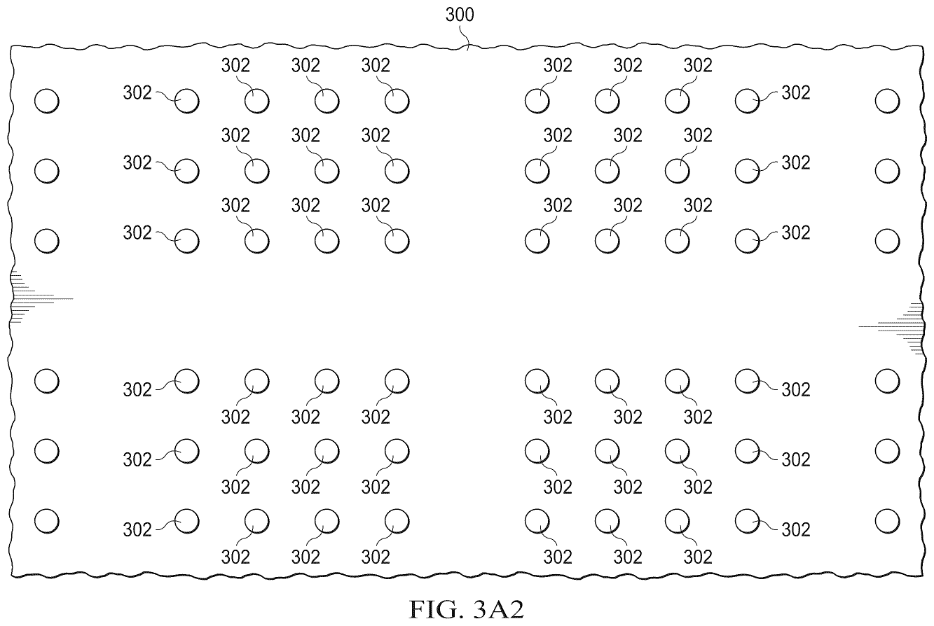

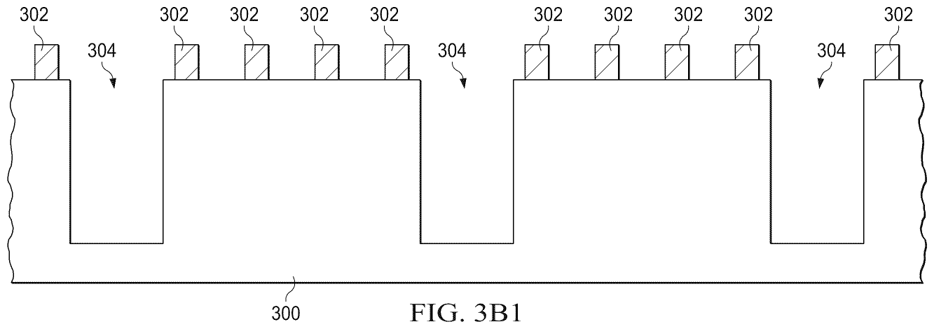

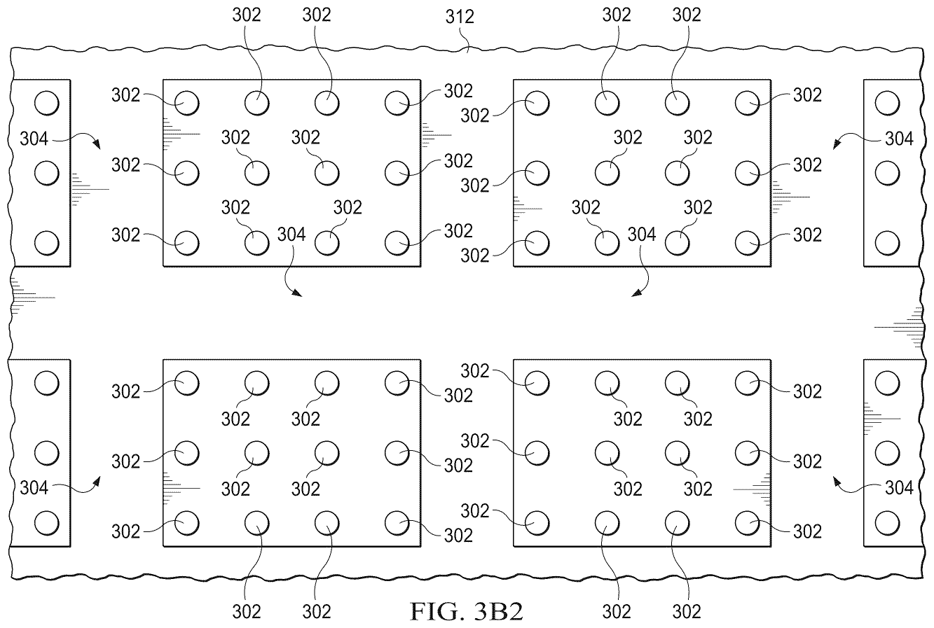

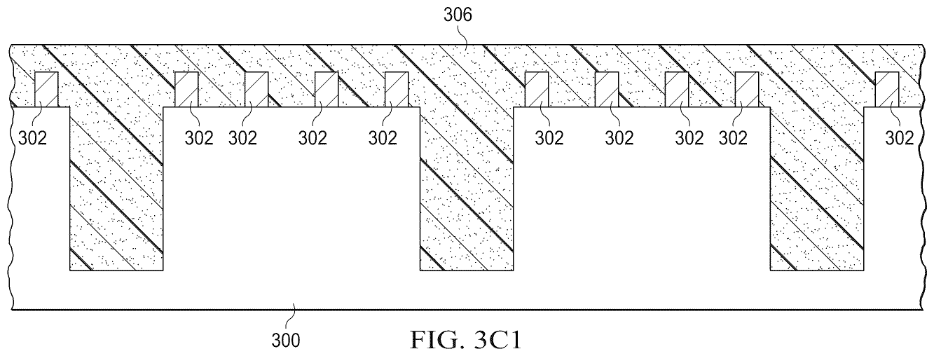

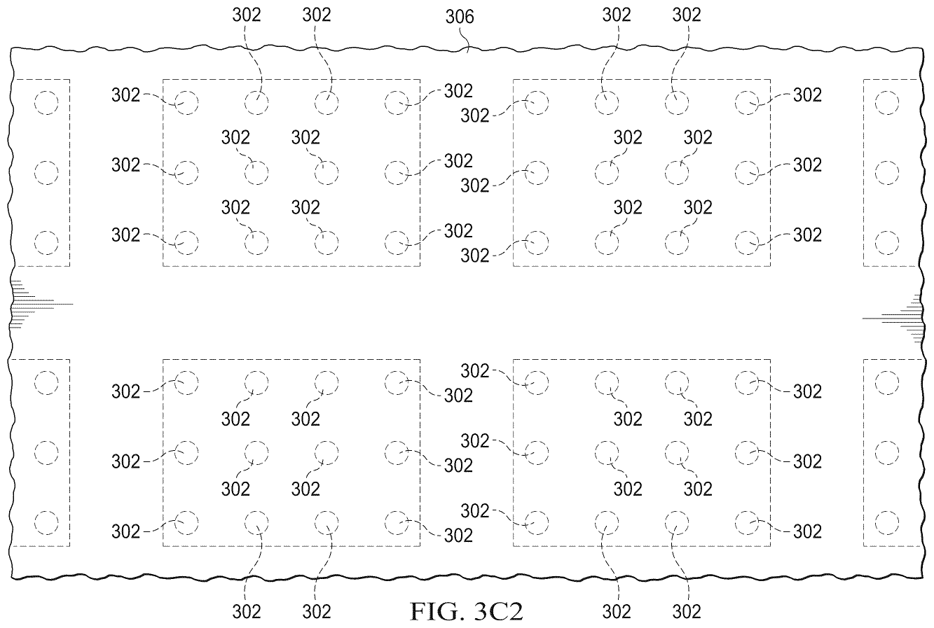

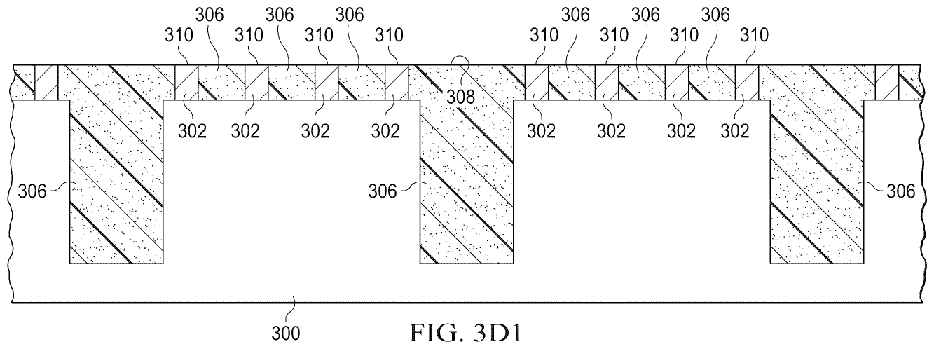

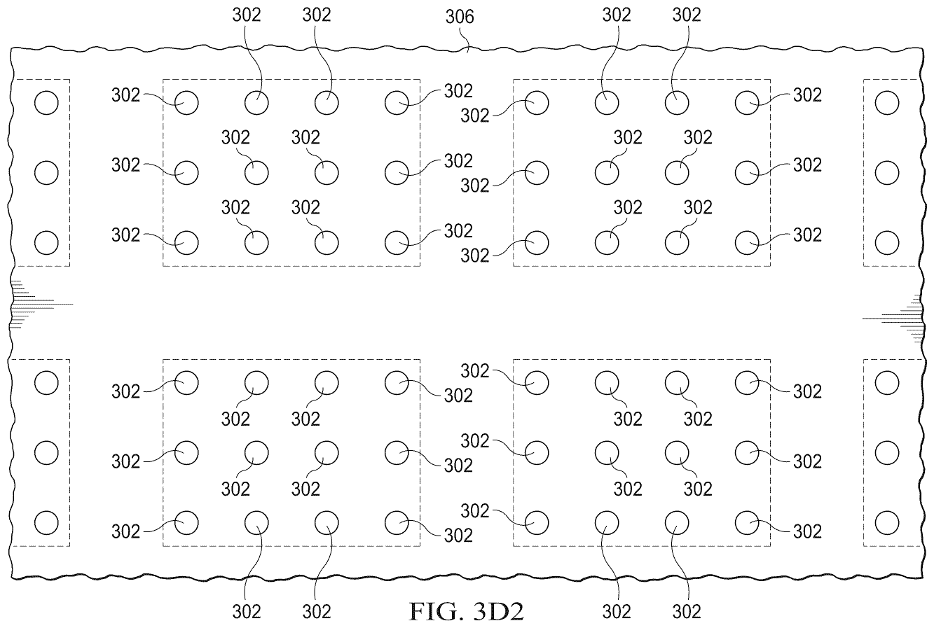

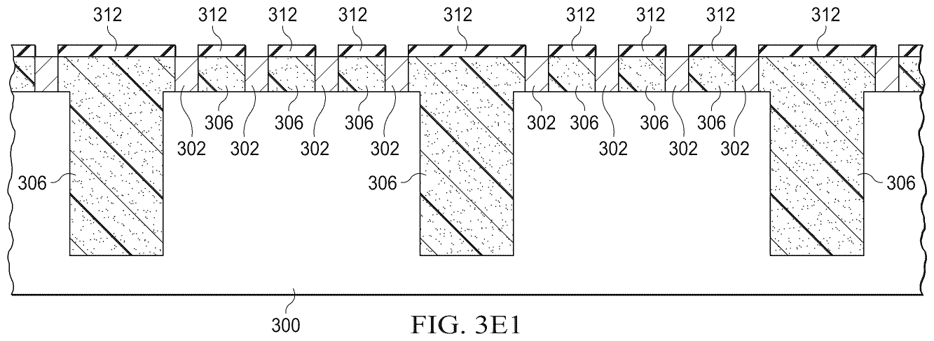

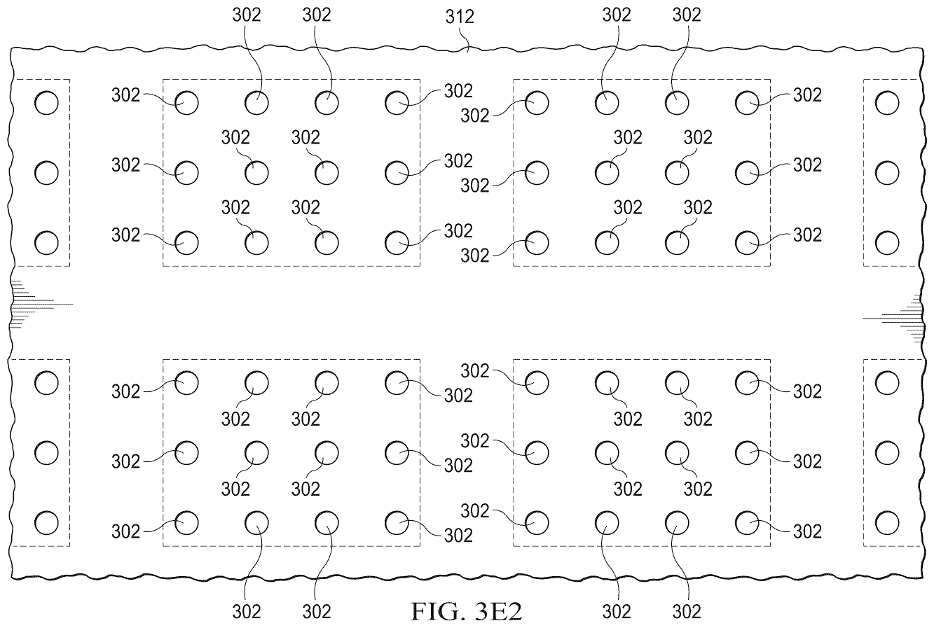

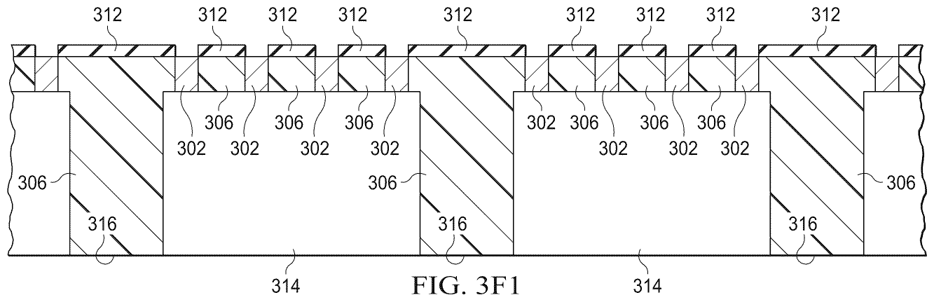

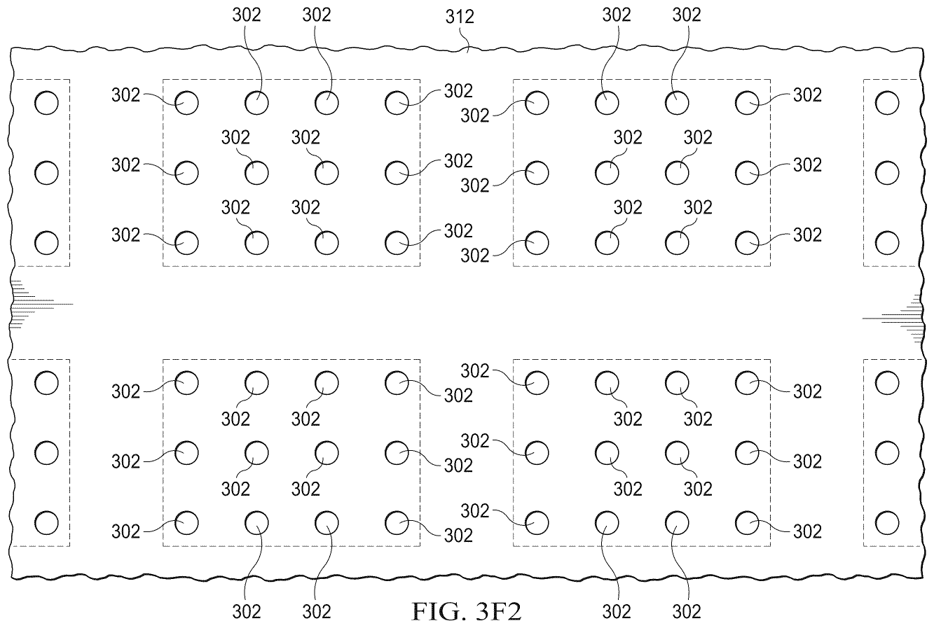

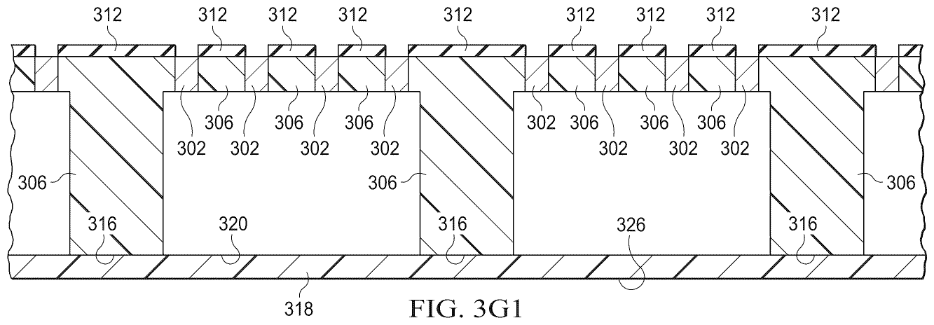

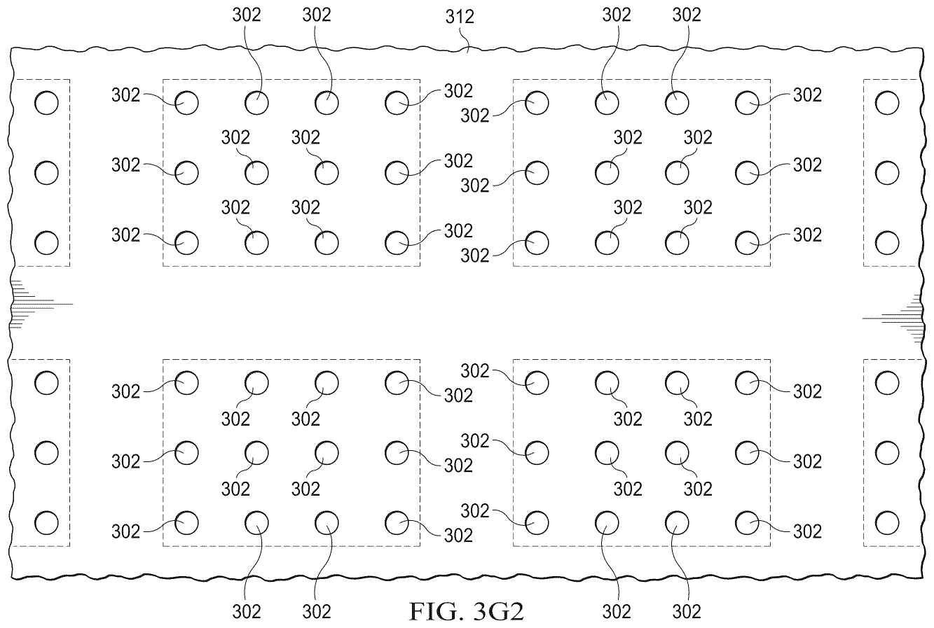

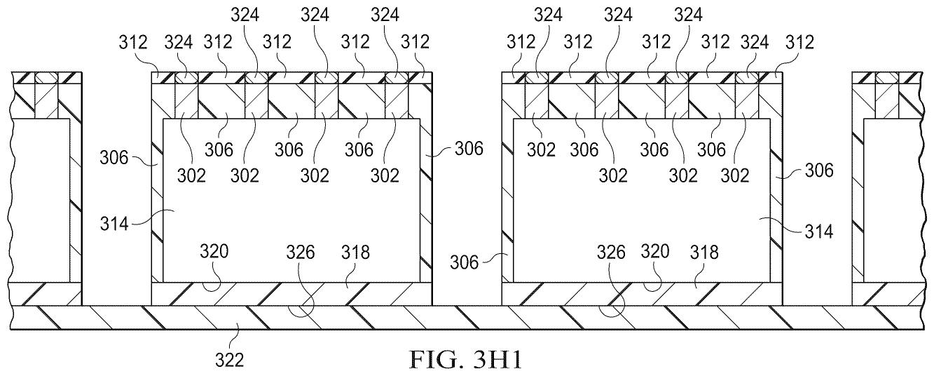

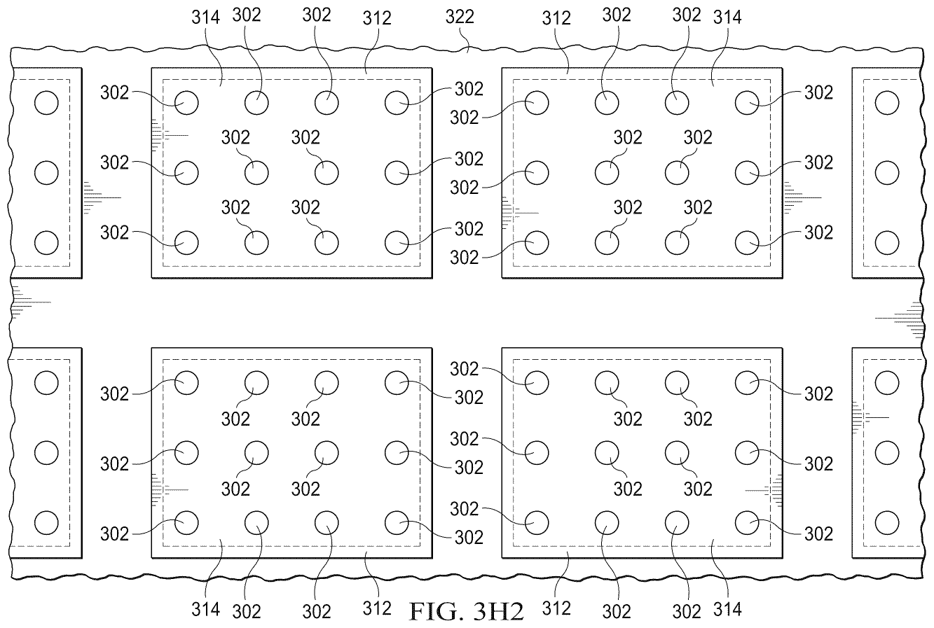

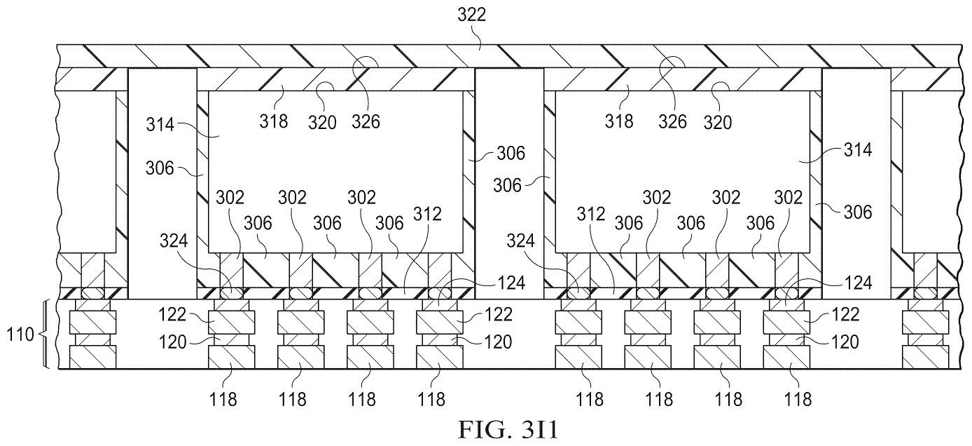

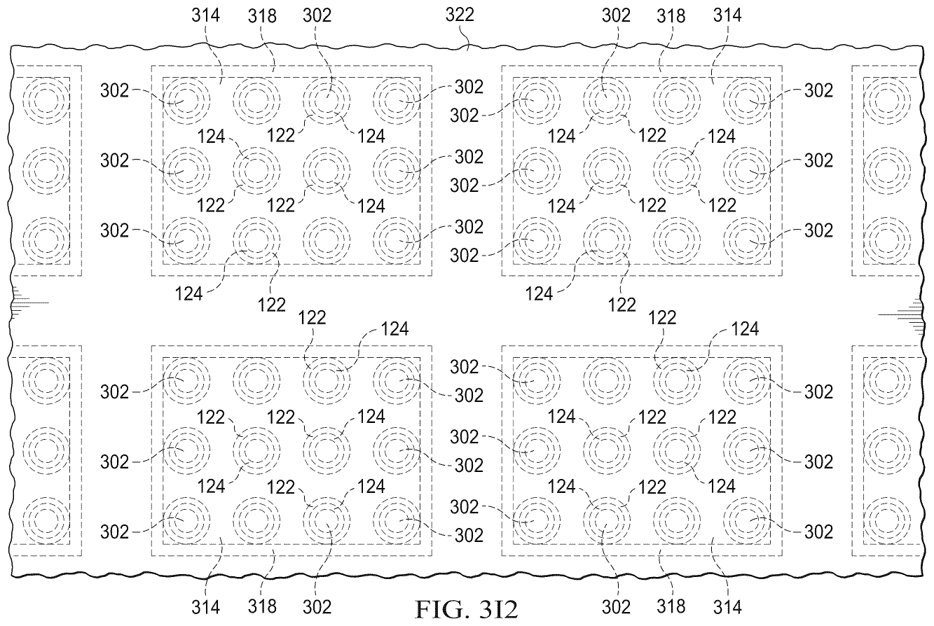

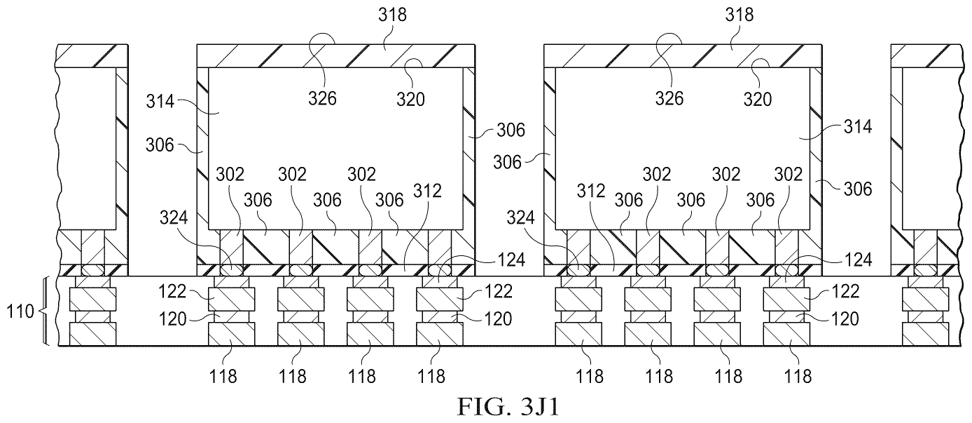

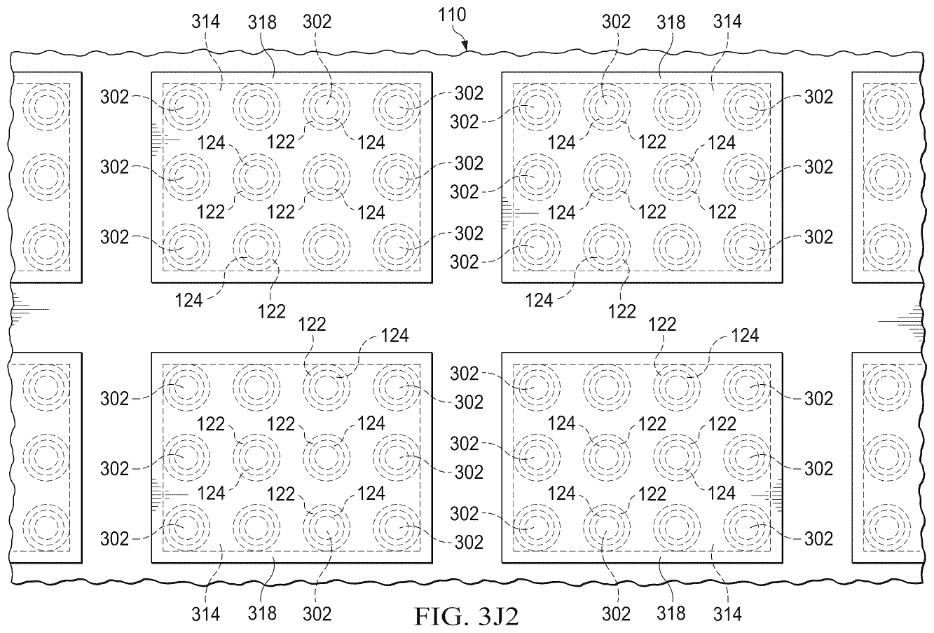

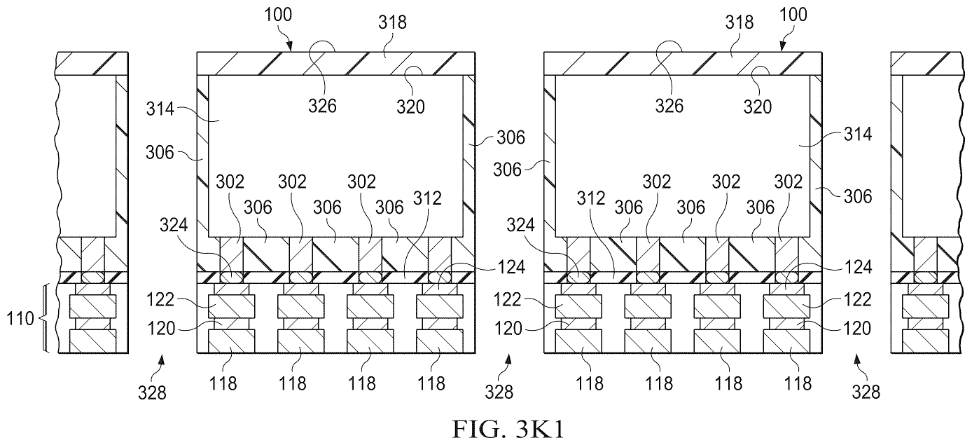

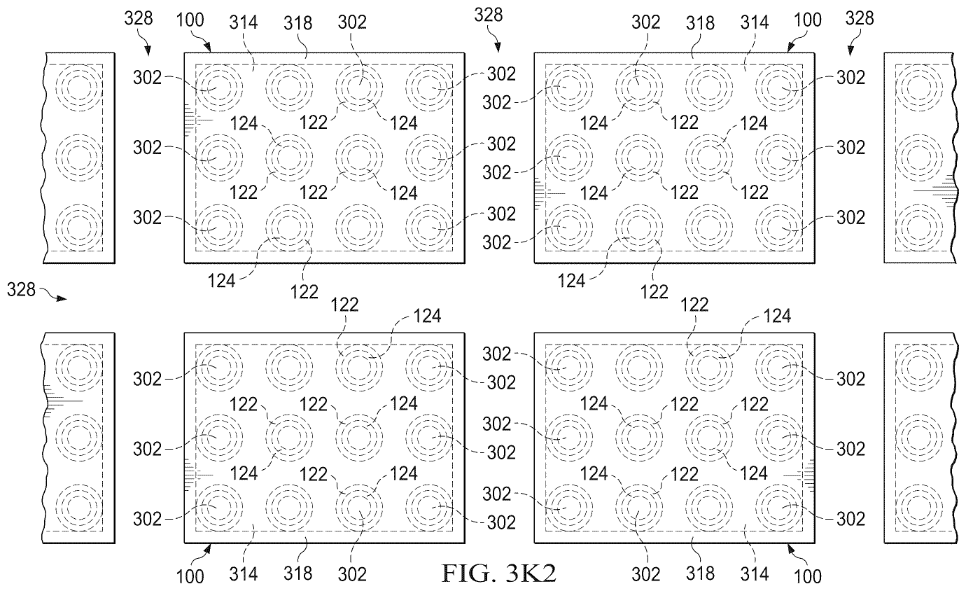

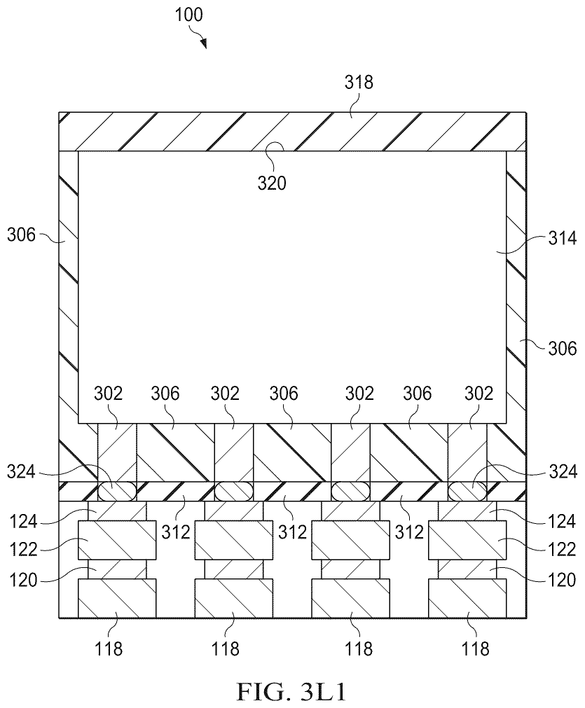

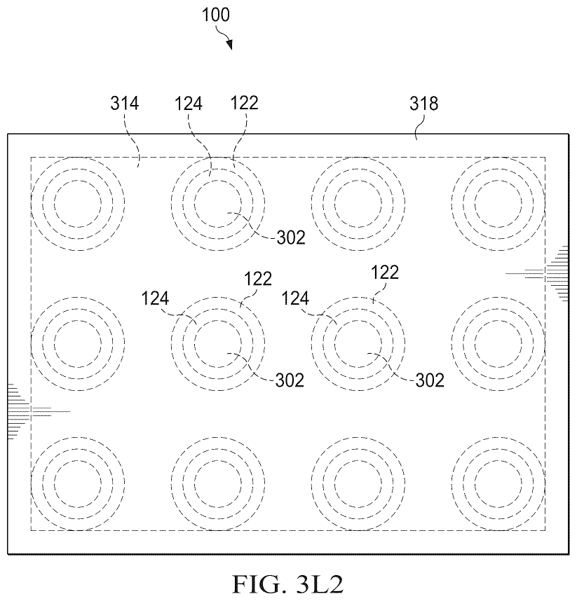

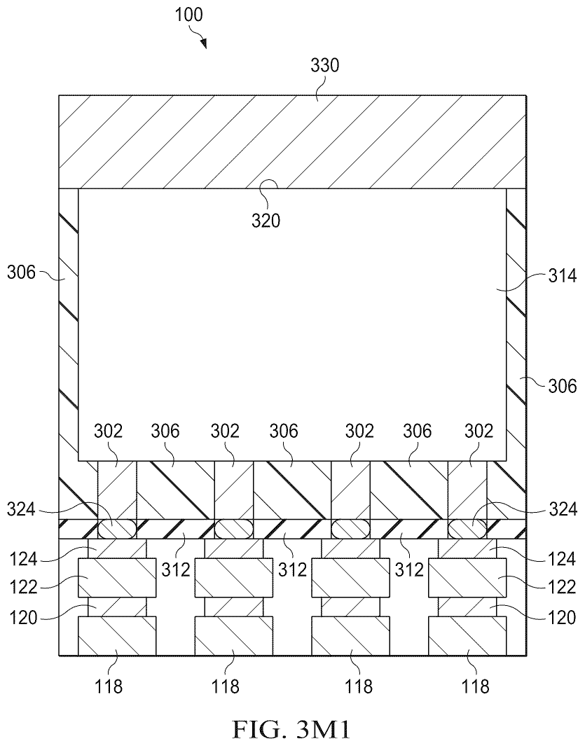

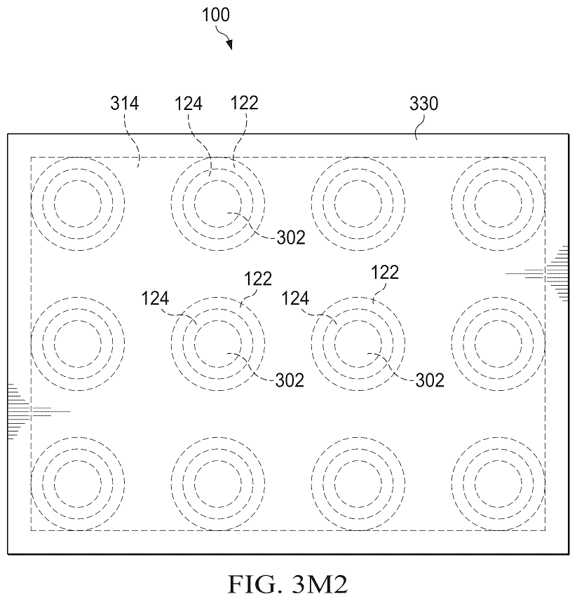

FIG. 2A is a flow diagram of a method 200 for manufacturing the substrate 110, in accordance with various examples. FIG. 2B is a flow diagram of a method 250 for manufacturing the semiconductor package 100, in accordance with various examples. FIGS. 3A1-3M2 are a process flow for manufacturing the semiconductor package 100, in accordance with various examples. Accordingly, FIGS. 2A, 2B, and 3A1-3M2 are now described in parallel.

The method 200 may include plating multiple cylindrical copper pillars on a base layer, which may include a seed layer (202). The method 200 may include covering (e.g., physically contacting) the multiple cylindrical copper pillars with a BUF, with the BUF between and physically contacting the multiple cylindrical copper pillars (204). The method 200 may include thinning the BUF to expose the multiple cylindrical copper pillars on a top surface of the BUF (206). In some examples, one or more of the steps 202, 204, and 206 may be performed through an iterative process. The iterative process may include plating a metal layer, either on a base layer (e.g., a seed layer), or on a previously plated metal layer or via. The metal layer may be plated using any suitable technique, such as a photolithography technique using the appropriate patterned masks. The BUF, or other dielectric, is then applied to the plated metal layer. The BUF or other dielectric may then be thinned such that the top surfaces of the metal layer are exposed through the top surface of the BUF or dielectric. The process is then iteratively repeated to form a via, then an optional second metal layer and optional second via, then an optional third metal layer and optional third via, etc. For simplicity, in FIG. 2A and the description thereof, the term “metal layer” may encompass both metal layers and vias (e.g., each component of the cylindrical copper pillar 114).

The method 250 may be performed after the substrate (e.g., the substrate 110) is formed using the method 200. The method 250 may include coupling copper posts to a device side of a semiconductor wafer, for example, by plating (252). FIG. 3A1 is a cross-sectional view of a semiconductor wafer 300 having copper posts 302 formed on the device side of the semiconductor wafer 300. FIG. 3A2 is a top-down view of the structure of FIG. 3A1.

The method 250 may include partially cutting through the semiconductor wafer from the device side of the semiconductor wafer to form cavities (254). This cutting may be performed by any suitable technique, such as a dry or wet etching technique. FIG. 3B1 is a cross-sectional view of the structure of FIG. 3A1, except that cavities 304 are formed on the device side of the semiconductor wafer 300. In examples, the cavities 304 extend at least halfway through the thickness of the semiconductor wafer 300, although the scope of this disclosure is not limited to any specific cavity depth. For example, the cavities 304 may extend to a depth equal to a target thickness of the semiconductor die 102 (FIG. 1A). Each cavity 304 is positioned between each set of four conductive terminals. The cavities 304 may be formed in a grid pattern, with four cavities 304 separating a set of four copper posts 302 from the remaining copper posts 302 of the semiconductor wafer 300. FIG. 3B2 is a top-down view of the structure of FIG. 3B1.

The method 250 may include applying a mold compound to a device side of the semiconductor wafer and into the cavities (256). FIG. 3C1 is a cross-sectional view of the structure of FIG. 3B1, except that a mold compound 306 is applied to the device side of the semiconductor wafer 300 and into the cavities 304. FIG. 3C2 is a top-down view of the structure of FIG. 3C1.

The method 250 may include thinning the mold compound to expose the top surfaces of the copper posts (258). FIG. 3D1 is a cross-sectional view of the structure of FIG. 3C1, except that the mold compound 306 is thinned so that the top surface 308 of the thinned mold compound 306 is approximately flush with top surfaces 310 of the copper posts 302. Stated another way, the mold compound 306 is thinned so that the top surfaces 310 are exposed. FIG. 3D2 is a top-down view of the structure of FIG. 3D1.

The method 250 may include applying and patterning a protective layer, such as a polyimide (PI) layer, on the top surface of the mold compound (260). FIG. 3E1 is a cross-sectional view of the structure of FIG. 3D1, except that a PI layer 312 has been applied to the top surface 308 of the mold compound 306 and has been patterned to remove portions of the PI layer 312 above the top surfaces 310 of the copper posts 302. FIG. 3E2 is a top-down view of the structure of FIG. 3E1.

The method 250 may include curing the mold compound (262) and backgrinding a non-device side of the semiconductor wafer opposite the device side until the semiconductor wafer is singulated into individual semiconductor dies (264). FIG. 3F1 is a cross-sectional view of the structure of FIG. 3E1, except that the mold compound 306 has been cured (e.g., by heating), and the semiconductor wafer 300 has been backgrinded until the semiconductor wafer 300 has been singulated into individual semiconductor dies 314, which also results in the exposure of the mold compound surfaces 316, as shown. FIG. 3F2 is a top-down view of the structure of FIG. 3F1.

The method 250 may include applying a mold compound to non-device sides of the semiconductor dies and curing the mold compound (266). FIG. 3G1 is a cross-sectional view of the structure of FIG. 3F1, except that additional mold compound 318 is applied to the non-device surfaces 320 of the semiconductor dies 314 and to the mold compound surfaces 316, as shown. FIG. 3G2 is a top-down view of the structure of FIG. 3G1.

The method 250 may include coupling a backgrind tape to the mold compound covering the non-device sides of the semiconductor dies (268), cutting through the mold compound to separate the multiple semiconductor dies from each other (270), and dropping solder balls on the copper posts (272). FIG. 3H1 is a cross-sectional view of the structure of FIG. 3G1, except that a backgrind tape 322 is coupled to the additional mold compound 318, the mold compounds 306 and 318 have been cut through (e.g., by a mechanical or laser saw) to separate the structure of FIG. 3G1 into individual devices, and solder bumps 324 are deposited into the openings of the PI layer 312, specifically, on the copper posts 302. The cutting tool (e.g., mechanical or laser saw) used to perform the cutting shown in FIG. 3H1 may have a cutting width, and the widths of the cavities 304 may be set, so that the thickness of the mold compound 306 on each lateral surface of each semiconductor die 314 is negligible, i.e., the ratio of the area of non-device surface 320 to the area of surface 326 is at least 0.90. As described, a ratio of at least 0.90 helps the resulting semiconductor package have a footprint and form factor identical to, or nearly identical to, that of a WCSP. FIG. 3H2 is a top-down view of the structure of FIG. 3H1.

The method 250 may include attaching copper posts to the substrate by reflowing the solder balls (274). FIG. 311 is a cross-sectional view of the structure of FIG. 3H1, except that the structure of FIG. 3H1 is coupled, by solder reflow, to the substrate 110. FIG. 3I2 is a top-down view of the structure of FIG. 3I1.

The method 250 may include removing the backgrind tape (276) and singulating the substrate to produce individual semiconductor packages (278). FIG. 3J1 is a cross-sectional view of the structure of FIG. 311, except that the backgrind tape 322 is removed. FIG. 3J2 is a top-down view of the structure of FIG. 3J1, in accordance with various examples. FIG. 3K1 is a cross-sectional view of the structure of FIG. 3J1, except that a cutting tool, such as a mechanical or laser saw, is used to cut through the substrate 110, as numeral 328 indicates, to produce individual semiconductor packages 100, as the cross-sectional view of FIG. 3L1 shows. FIG. 3K2 is a top-down view of the structure of FIG. 3K1, and FIG. 3L2 is a top-down view of the structure of FIG. 3L1. The method 250 may then include coupling an individual semiconductor package 100 to a PCB and including the PCB within an electronic device (280).

In some examples, the additional mold compound 318 (FIG. 3G1) may not be applied. In such examples, the non-device surfaces 320 may be exposed. Heat sinks 330 may be coupled to the non-device surfaces 320 to facilitate heat expulsion, for example, as the cross-sectional view of FIG. 3M1 shows. FIG. 3M2 is a top-down view of the structure of FIG. 3M1.

The steps of the method 250 may be performed in any suitable order. However, in at least some examples, the steps of the method 250 are performed in the specific sequence shown.

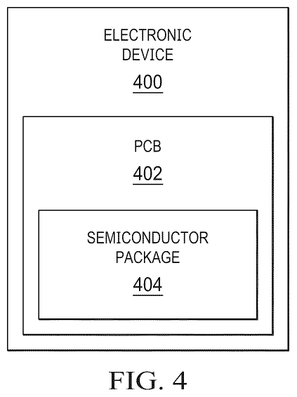

FIG. 4 is a block diagram of an electronic device 400 including a small form factor semiconductor package 404 with low electromigration coupled to a PCB 402, in accordance with various examples. Examples of the electronic device 400 include an automobile, an aircraft, a watercraft, a spacecraft, a video game console, an arcade video game unit, a smartphone, an entertainment device, an appliance, a laptop computer, a desktop computer, a tablet, a notebook, or any other suitable type of electronic device or system.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through a construction and/or layout of hardware components and interconnections of the device.

In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a semiconductor die having a device side in which circuitry is formed;
multiple copper posts coupled to the device side of the semiconductor die;
a substrate coupled to the multiple copper posts by solder joints, the substrate comprising:
cylindrical copper pillars extending from the solder joints on a top surface of the substrate to a bottom surface of the substrate, the copper pillars having circular or ovoid bottom surfaces exposed to the bottom surface of the substrate; and
a build-up film between and physically contacting the copper pillars; and
a mold compound physically contacting the semiconductor die, the multiple copper posts, and the top surface of the substrate.

2. The semiconductor package of claim 1, wherein a solder-to-copper volumetric ratio of one of the solder joints to a combination of one of the multiple copper posts and one of the cylindrical copper pillars ranges from 0.08 to 0.13.

3. The semiconductor package of claim 2, wherein the one of the solder joints has a thickness ranging from 10 microns to 30 microns.

4. The semiconductor package of claim 2, wherein the one of the multiple copper posts has a thickness ranging from 40 microns to 60 microns.

5. The semiconductor package of claim 2, wherein the one of the cylindrical copper pillars has a thickness ranging from 100 microns to 200 microns.

6. The semiconductor package of claim 1, wherein a ratio of an area of a non-device side of the semiconductor die opposite the device side in the horizontal direction to an area of a top surface of the mold compound in the horizontal direction is at least 0.90.

7. The semiconductor package of claim 1, wherein the build-up film includes an epoxy resin, ceramic filler particles, and a curing agent.

8. The semiconductor package of claim 1, wherein one of the cylindrical copper pillars includes first and second members, the second member closer to the semiconductor die than the first member, the first member having a larger horizontal area than the second member.

9. The semiconductor package of claim 1, wherein the circular or ovoid bottom surfaces are positioned in a multi-dimensional array including columns and rows of the circular or ovoid bottom surfaces.

10. The semiconductor package of claim 1, further comprising a heat sink coupled to a non-device side of the semiconductor die opposite the device side of the semiconductor die.

11. The semiconductor package of claim 1, wherein the substrate lacks metal components having lengths that extend in the horizontal direction.

12. The semiconductor package of claim 1, wherein the substrate includes a single metal layer and a single via layer physically contacting the single metal layer, and wherein the substrate does not include any additional metal or via layers beyond the single metal layer and the single via layer.

13. A semiconductor package, comprising:
a semiconductor die having a device side in which circuitry is formed;
multiple copper posts coupled to the device side of the semiconductor die;
a substrate coupled to the multiple copper posts by solder joints, the substrate comprising:
cylindrical copper pillars extending from the solder joints on a top surface of the substrate to a bottom surface of the substrate, the copper pillars having circular or ovoid bottom surfaces exposed to the bottom surface of the substrate in an array, wherein a solder-to-copper volumetric ratio of one of the solder joints to a combination of one of the multiple copper posts and one of the cylindrical copper pillars ranges from 0.08 to 0.13; and
a build-up film between and physically contacting the copper pillars; and
a mold compound physically contacting the semiconductor die, the multiple copper posts, and the top surface of the substrate, wherein a ratio of an area of a non-device side of the semiconductor die opposite the device side in the horizontal direction to an area of a top surface of the mold compound in the horizontal direction is at least 0.90.

14. The semiconductor package of claim 13, wherein the one of the solder joints has a thickness ranging from 10 microns to 30 microns.

15. The semiconductor package of claim 13, wherein the one of the multiple copper posts has a thickness ranging from 40 microns to 60 microns.

16. The semiconductor package of claim 13, wherein the one of the cylindrical copper pillars has a thickness ranging from 100 microns to 200 microns.

17. The semiconductor package of claim 13, wherein the build-up film includes an epoxy resin, ceramic filler particles, and a curing agent.

18. The semiconductor package of claim 13, wherein the one of the cylindrical copper pillars includes first and second members, the second member closer to the semiconductor die than the first member, the first member having a larger horizontal area than the second member.

19. The semiconductor package of claim 13, wherein the circular or ovoid bottom surfaces are positioned in a multi-dimensional array including columns and rows of the circular or ovoid bottom surfaces.

20. The semiconductor package of claim 13, further comprising a heat sink coupled to a non-device side of the semiconductor die opposite the device side of the semiconductor die.

21. The semiconductor package of claim 13, wherein the substrate lacks metal components having lengths that extend in the horizontal direction.

22. The semiconductor package of claim 13, wherein the substrate includes a single metal layer and a single via layer physically contacting the single metal layer, and wherein the substrate does not include any additional metal or via layers beyond the single metal layer and the single via layer.

23. A method for manufacturing a semiconductor package, comprising:
forming a substrate by plating multiple cylindrical copper pillars and covering the multiple cylindrical copper pillars with a build-up film, the build-up film between and contacting the multiple cylindrical copper pillars;
coupling copper posts to a device side of a semiconductor wafer, the device side including circuitry;
partially cutting through the semiconductor wafer from the device side of the semiconductor wafer to form cavities;
applying a mold compound to the device side of the semiconductor wafer and in the cavities;
thinning the mold compound to expose the copper posts;
curing the mold compound;
backgrinding a non-device side of the semiconductor wafer opposite the device side until the semiconductor wafer is divided into multiple semiconductor dies;
cutting through the mold compound to separate the multiple semiconductor dies from each other;
coupling the multiple semiconductor dies to the multiple cylindrical copper pillars of the substrate; and
cutting through the substrate in between the multiple semiconductor dies to form individual semiconductor packages.

24. The method of claim 23, wherein the cutting through the mold compound is performed after applying the mold compound and backgrinding the non-device side of the semiconductor wafer.

25. The method of claim 23, further comprising applying additional mold compound to a non-device side of the semiconductor wafer opposite the device side of the semiconductor wafer.

26. The method of claim 23, wherein the build-up film includes an epoxy resin, ceramic filler particles, and a curing agent.
